(19) United States
(12) Patent Application Publication
(10) Pub. No.: US 2024/0410773 A1
(43) Pub. Date: Dec. 12, 2024

(54) Integrated Pressure Sensor for Process Chamber Assemblies

(71) Applicant: Applied Materials, Inc., Santa Clara, CA (US)

(72) Inventors: Chih-Yang CHANG, Santa Clara, CA (US); Shantanu Rajiv GADGIL, Santa Clara, CA (US); Chien-Min LIAO, San Jose, CA (US); Shannon WANG, Santa Clara, CA (US); Yao-Hung YANG, Santa Clara, CA (US); Tom K. CHO, Los Altos, CA (US)

(21) Appl. No.: 18/208,010

(22) Filed: Jun. 9, 2023

(51) Int. Cl. G01L 13/06; C23C 16/455; C23C 16/52; G01M 13/005

(52) U.S. Cl. CPC G01L 13/06; C23C 16/45525; C23C 16/45565; C23C 16/52; G01M 13/005

(57) ABSTRACT

Methods and apparatus provide in-situ pressure sensors for apparatus used in semiconductor manufacturing processes. In some embodiments, the apparatus may comprise a showerhead body, a first gas channel of the showerhead body, a second gas channel of the showerhead body, one or more first gas pressure sensors positioned on a surface of the first gas channel, and one or more second gas pressure sensors positioned on a surface of the second gas channel. The apparatus may be formed by additive manufacturing including the pressure sensors and electrical connections to the pressure sensors. In some embodiments, a controller may be utilized to control semiconductor processes based on the pressure readings from the in-situ pressure sensors.

### FIELD

Embodiments of the present principles generally relate to processing of semiconductor substrates.

### BACKGROUND

Some semiconductor chambers employ gases during processing of substrates. The gases typically flow through channels that deliver the gases to a processing volume. Multiple channels may be used to flow different gases where each channel is separated by a gasket. If the gasket begins to fail, crosstalk between the separated gas channels may occur, causing poor process performance due to the mixing of the gases and/or the loss of gas pressure in a gas channel. Normally, the gradual failing of the gasket is not easily detectable and eventually a total gasket failure occurs, halting production unexpectedly, causing downtime and loss of yield.

Accordingly, the inventors have provided an apparatus and methods for providing in-situ pressure monitoring, for example, to provide early gasket failure detection, reducing downtime and increasing yield.

### SUMMARY

Methods and apparatus for in-situ pressure monitoring of gas channeling assemblies are provided herein.

In some embodiments, an apparatus for substrate processing in a process chamber may comprise a showerhead body, a first gas channel of the showerhead body, and one or more first gas pressure sensors positioned on a surface of the first gas channel. A second gas channel of the showerhead body with one or more second gas pressure sensors that are positioned on a surface of the second gas channel may also be incorporated into the apparatus. In some instances, the first gas channel and the second gas channel are both spiral channels that are interleaved with each other.

In some embodiments, a pressure monitor may be electrically connected to the one or more first gas pressure sensors and the one or more second gas pressure sensors and configured to detect differential pressure between the one or more first gas pressure sensors and the one or more second gas pressure sensors. A controller may also be in communication with the pressure monitor and configured to alter a process in the process chamber based on the differential pressure or based on a pressure provided by the one or more first gas pressure sensors. The showerhead body may be formed by an additive manufacturing process and the one or more first gas pressure sensors may be formed by the additive manufacturing process and embedded into the one or more first surfaces. The showerhead body may also comprise two separate pieces with a gasket material positioned therebetween.

In some embodiments, a method for forming an assembly for a process chamber may comprise forming a showerhead body, forming a first gas channel of the showerhead body, and forming one or more first gas pressure sensors positioned on a surface of the first gas channel using an additive manufacturing process. A second gas channel of the showerhead body with one or more second gas pressure sensors that are positioned on a surface of the second gas channel may also be formed in the showerhead body.

In some embodiments, one or more first gas pressure sensors may be electrically connected to the one or more first gas pressure sensors and the one or more second gas pressure sensors and to a controller that detects differential pressure between the one or more first gas pressure sensors and the one or more second gas pressure sensors. The controller may halt a process in the process chamber based on the differential pressure or alter a process in the process chamber based on a pressure provided by the one or more first gas pressure sensors to the controller.

In some embodiments, a non-transitory, computer readable medium having instructions stored thereon that, when executed, cause a method for forming an apparatus of a process chamber to be performed, the method may comprise forming a showerhead body using an additive manufacturing process, forming a first gas channel of the showerhead body during the additive manufacturing process, forming a second gas at a second gas channel of the showerhead body during the additive manufacturing process, forming one or more first gas pressure sensors positioned on a surface of the first gas channel during additive manufacturing process, and forming one or more second gas pressure sensors positioned on a surface of the second gas channel during the additive manufacturing process. The method may also include forming electrical connections to the one or more first gas pressure sensors and the one or more second gas pressure sensors through the showerhead body during the additive manufacturing process.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of a process chamber in accordance with some embodiments of the present principles.

FIG. 2 depicts a cross-sectional view of a top plate of a showerhead with a spiral gasket groove in accordance with some embodiments of the present principles.

FIG. 3 depicts an isometric view of a contact printer in accordance with some embodiments of the present principles.

FIG. 4 depicts a cross-sectional view of a contact print head in accordance with some embodiments of the present principles.

FIG. 5 depicts cross-sectional views of a top plate of a showerhead being formed in accordance with some embodiments of the present principles.

FIG. 6 depicts cross-sectional views of a bottom plate of a showerhead being formed in accordance with some embodiments of the present principles.

FIG. 7 depicts top-down and isometric views of pressure sensor connections in accordance with some embodiments of the present principles.

FIG. 8 depicts a cross-sectional view of a top plate of a showerhead and a bottom plate of a showerhead with embedded pressure sensors in accordance with some embodiments of the present principles.

FIG. 9 depicts a cross-sectional view of a monolithic showerhead with embedded pressure sensors in accordance with some embodiments of the present principles.

FIG. 10 depicts an isometric view of a top plate of a showerhead with a dual gas channel cooling and with embedded pressure sensor pairs in accordance with some embodiments of the present principles.

FIG. 11 depicts a cross-sectional view of a top plate of a showerhead with a dual gas channel cooling apparatus and a bottom plate of a showerhead with embedded pressure sensor pairs in accordance with some embodiments of the present principles.

FIG. 12 depicts top-down and cross-sectional views of different types of pressure sensors in accordance with some embodiments of the present principles.

FIG. 13 is a method for forming an assembly of a process chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide in-situ monitoring of pressure in gas channels of a semiconductor process chamber. The pressure sensors are three-dimensionally printed in a gas channel either after formation of an apparatus and/or in conjunction with the three-dimensional (3D) printing of the apparatus. The 3D printed pressure sensors allow the sensors to be positioned exactly at critical points to provide advanced notice of assembly failures such as gasket failures. The advanced notice allows for parts to be automatically ordered ahead of time and/or to know when the semiconductor process chamber should be halted to avoid defects in substrate processing, avoiding the scrapping of defective substrates. The 3D printed pressure sensors may also be used during the substrate processing by providing pressure information at specific points of an apparatus to allow greater control of the process. In addition, the 3D printed pressure sensors are economical and may be incorporated into the apparatus such that gas flow properties are not hindered.

In current chamber apparatus designs, no real-time pressure information is available during substrate processing. Gas pressures are controlled via valves on a gas supply source and pressure inside of apparatus is assumed to be the same as the gas supply source based on the flow valve settings. The present techniques allow pressure monitoring internal to the process chamber apparatus and provide higher pressure accuracy and/or fault detection capabilities. The techniques allow for incorporation during the manufacturing of the apparatus and/or after the manufacturing of the apparatus. For the sake of brevity, the examples of apparatus that may have in-situ pressure sensors incorporated within the assemblies may be gas coolant apparatus (e.g., a waterbox, etc.) and/or showerhead apparatus (e.g., top plate and/or bottom plate, etc.) and the like. However, such apparatus are not meant to be limiting, as the 3D printed pressure sensors may be used in other apparatus as well (e.g., substrate supports, chucks, backside gas delivery systems, etc.).

The inventors have observed that for multiple part assemblies that employ gaskets between the parts to ensure separation of individual gas channels, an unexpected failure of the gasket may lead to defective substrates along with downtime and parts availability issues. In some cases, the gaskets may be hand installed and, thus, different installers may cause deformities in the gaskets due to stretching during installation. The inventors have noted over time that specific locations within the assemblies are more likely to fail than at other locations. The present techniques allow for gasket performance monitoring by measuring the pressure in a gas channel at specific locations. In addition, adjacent gas channels carrying different gases can be monitored to detect pressure anomalies to avoid a gas leaking into another gas channel and causing substrate defects and/or lower performance of the process chamber process.

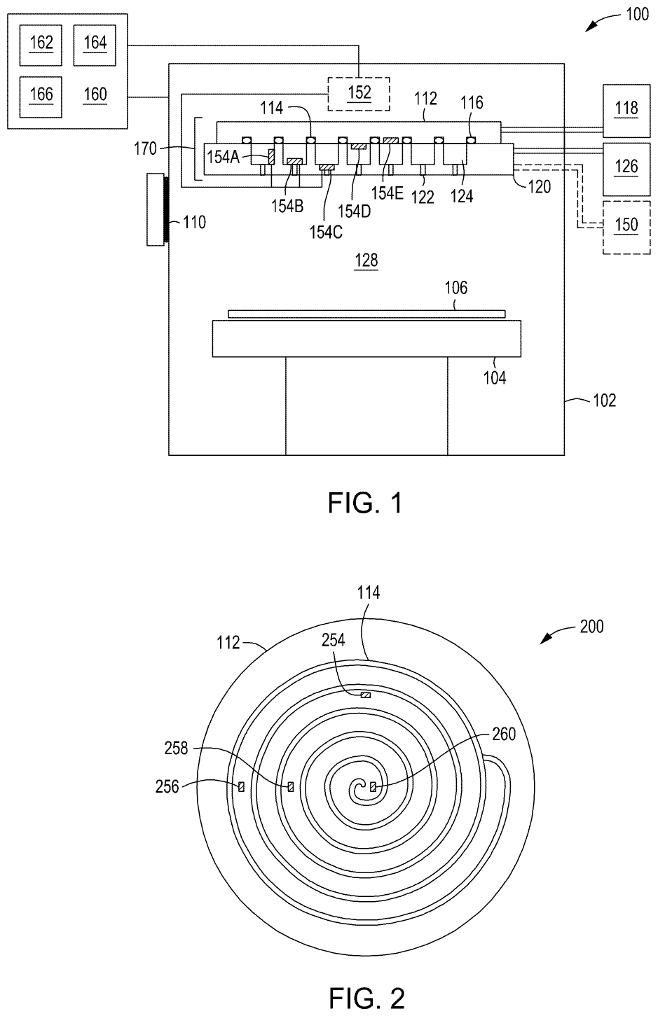

The apparatus and methods of the present principles may be used in the formation of in-situ pressure sensors for any type of part or apparatus used in the manufacturing of substrates. For example, but not meant to be limiting, in FIG. 1 is a process chamber 100 used in semiconductor substrate manufacturing. The process chamber 100 has walls 102 that enclose a substrate support 104 and a processing volume 128 with a loading slot 110. The substrate support 104 is used to support a substrate 106 during processing. The process chamber 100 may be used in chemical vapor deposition (CVD) processes or atomic layer deposition (ALD) processes and includes a showerhead 170 comprising a top plate 112 and a bottom plate 120. The top plate 112 may also comprise a cooling apparatus to control the temperature of the showerhead 170. The bottom plate 120 includes gas channels 124 and gas nozzles 122 to distribute a first gas from a first gas supply 126 into the processing volume 128. In some embodiments, the bottom plate 120 may have an optional second gas supply 150 that provides a second gas via separate channels from the first gas into the processing volume 128.

The top plate 112 includes a gasket 116 that is positioned within gasket groove 114 to keep the gas channels 124 of the bottom plate 120 separated. In the case of a second gas, the gasket 116 keeps the first gas and the second gas separated. The top plate 112 is connected to a cooling liquid supply 118. The inventors have observed that the process chamber 100 has thermal and gas leak damage in the showerhead 170 after substrate processing. Upon further inspection, poor sealing of the gasket 116 caused leakage between the gas channels 124 and wastage of substrates that were improperly processed. The extent of the leakage was not revealed until disassembly of the showerhead 170 and inspection of the top plate 112. To ascertain the condition of the gasket 116 during processing, the inventors sought to monitor the gasket sealing properties in real-time. By positioning at least one pressure sensor within the apparatus (e.g., bottom plate 120, top plate 112, etc.), internal pressure could be monitored in real-time and used to determine the sealing condition of the gasket 116 (e.g., decreasing pressure may indicate a failing gasket or sealing surface, etc.). However, placing a pressure sensor inside of an apparatus is complicated, as the pressure sensor must communicate the pressure information to an external location to have any value to the operation of the process chamber 100. In addition, the size of the pressure sensor must be compatible with the area being monitored (e.g., gas channel size, etc.).

The inventors discovered that by using an additive manufacturing process for the pressure sensor, the pressure sensor can be 3D printed and formed to accommodate spacing requirements as needed. In addition, the assembly can also be formed using additive manufacturing processes with the pressure sensors formed in the same process, including any signal wires needed for operation of the pressure sensors and monitoring of the pressures within an operational assembly. FIG. 1 depicts several positions where one or more pressure sensors may be located. A first pressure sensor 154A is positioned against a sidewall surface of the gas channels 124 in the bottom plate 120. A second pressure sensor 154B is positioned on a bottom surface of the gas channels 124 in the bottom plate 120. A third pressure sensor 154C is embedded into the bottom surface of the gas channels 124 of the bottom plate 120. A fourth pressure sensor 154D is positioned on a surface of the top plate 112. A fifth pressure sensor 154E is embedded into the surface of the top plate 112. The additive manufacturing of the pressure sensor allows for flexible placement of the pressure sensor and for retrofitting of existing assemblies. For example, existing assemblies can have pressure sensors printed directly on a surface of the existing assemblies and have milling and/or drilling performed to properly route any connecting wires to an external location of the assemblies. The pressure sensors of the present principles are smaller and more compact compared to traditional sensors. The pressure sensors have the ability to detect channel-to-channel leakage early to prevent wasting of resources and substrates. The pressure sensors also enable the ordering of new parts earlier based on the pressure sensor readings/warnings to reduce downtime caused by failed gaskets.

In some embodiments, the pressure sensors may be in communication with an optional pressure monitor 152 that determines differential pressures of the pressure sensors. The optional pressure monitor 152 can determine that a seal between a gas channel with a first gas at pressure A and a separated gas channel with a second gas at pressure B has been compromised by monitoring the pressure differential. For example, if gas pressure A is higher than gas pressure B, if the pressure monitor sees that gas pressure A=gas pressure B (gas differential pressure of zero), the seal between the gas channels is compromised and the user or controller 160 can be notified of a faulty condition. The controller 160 may be in communication directly with the pressure sensors and/or the optional pressure monitor 152. In some embodiments, the optional pressure monitor 152 may be located within the controller 160. The controller 160 monitors pressure values received from the pressure sensors to determine the health and/or faults of the assemblies and/or sealing surfaces. The pressure sensors may serve two purposes, the first is to detect faults that require maintenance of the apparatus and the second is to monitor real-time pressure values within the apparatus for enhanced process control. For instance, rather than use incoming gas supply pressure values for a process recipe, actual pressure values within the showerhead 170 could be used as feedback during the process to alter process recipes, for example, to better control uniformity during depositions and the like.

The controller 160 achieves the aforementioned by controlling the operation of the process chamber 100. The controller 160 may use a direct control of the process chamber 100, or alternatively, by controlling the computers (or controllers) associated with the process chamber 100. In operation, the controller 160 enables data collection and feedback from the process chamber 100 to optimize performance of the process chamber 100 and to control the processing flow and/or resolve any errant conditions by halting the process, alerting a user, and/or automatically making maintenance and/or parts ordering tasks occur. The controller 160 generally includes a central processing unit (CPU) 162, a memory 164, and a support circuit 166. The CPU 162 may be any form of a general-purpose computer processor that can be used in an industrial setting. The support circuit 166 is conventionally coupled to the CPU 162 and may comprise a cache, clock circuits, input/output subsystems, power supplies, and the like. Software routines, such as methods as described herein may be stored in the memory 164 and, when executed by the CPU 162, transform the CPU 162 into a specific purpose computer (controller 160). The software routines may also be stored and/or executed by a second controller (not shown) that is located remotely from the process chamber 100.

The memory 164 is in the form of computer-readable storage media that contains instructions, when executed by the CPU 162, to facilitate the operation of the semiconductor processes and equipment. The instructions in the memory 164 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored, and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The inventors have observed that the installation of the gasket 116 by hand led to stretching and gasket sealing inconsistencies during substrate processing. Some areas of the apparatus were more affected than others. As depicted in bottom-up view 200 of FIG. 2, the top plate 112 has a gasket groove 114 that spirals from the center outward. As the gasket 116 is installed, the installer tends to stretch the gasket in specific areas. The inventors found that by placing the pressure sensors in the fault prone areas, the gasket 116 failure could be detected early and the substrate processing halted and/or replacement parts ordered based on the pressure readings from the pressure sensors. For example, a first pressure sensor 260 can be placed at the center region of the top plate 112, a second pressure sensor 258 can be placed radially outward of the center region at a middle region of the top plate 112, and a third pressure sensor 256 can be placed radially outward of the middle at an outer region of the top plate 112. By using the three pressure sensors, the gasket 116 sealing properties can be monitored across the entire apparatus. If an additional problem area or region is known for losing sealing properties, other pressure sensors can be positioned on the apparatus such as a fourth pressure sensor 254. The top plate 112 is used for example purposes only and, likewise, the pressure sensors can be positioned similarly in the bottom plate 120 or the pressure sensors can be positioned by positioning some in surfaces of the top plate 112 and some in surfaces of the bottom plate 120. The present principles are also not limited to use with only showerheads or cooling apparatus but may, for example, be used with other assemblies such as an assembly in the substrate support 104 that provides backside gases to a substrate during processing and the like.

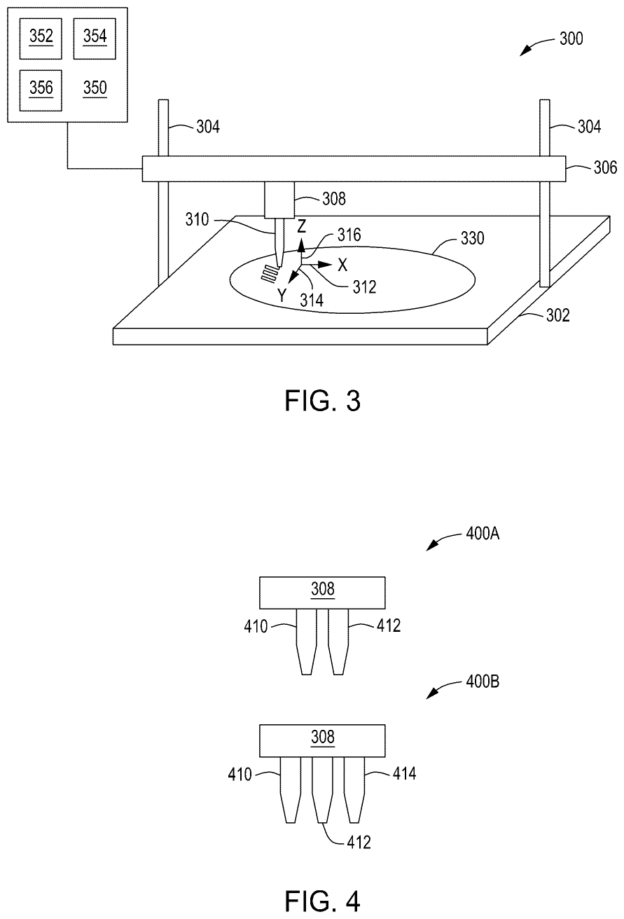

The pressure sensor and/or the apparatus may be formed using an additive manufacturing process such as, for example but not limited to, a contact printer 300 which may be used to print the pressure sensor 154 and/or the apparatus (e.g., bottom plate 120, top plate 112, etc.) as depicted in FIG. 3. The contact printer 300 has a base 302 that holds the apparatus 330 as a printer head 308 deposits material through one or more nozzles 310 and moves back and forth in an X direction 312 on a printer head support 306. The printer head support 306 is held above the base 302 by supports 304. In some embodiments, the printer head 308 and one or more nozzles 310 may also move back and forth in a Y direction 314 or the base 302 may move back and forth in a Y direction. By controlling the X and Y directions, the printer head 308 and one or more nozzles 310 can create linear and non-linear shapes (e.g., curves, rectangles, circles, spirals, etc.). In an example depicted in FIG. 3, a linear printing example shows the printer head 308 and the one or more nozzles 310 printing a pressure circuit. The printer head 308 and nozzle 310 also move in a Z direction 316 as each layer of filament is deposited to add height to the formation of the apparatus 330. The contact printer 300 also includes a controller 350 that has a computer processing unit (CPU) 352, a memory 354, and supporting circuits 356. The controller 350 allows the contact printer to adjust the printing of a pressure sensor and/or apparatus based on desired dimensions. The controller 350 can also be used to change the shape of an apparatus and/or pressure sensor during or prior to printing of the object, change or alter printing materials during or prior to printing of the object.

The formation of the apparatus and/or pressure sensor may be formed, in part, using a thermoplastic material such as, but not limited to, a thermoplastic polyurethane, a thermoplastic elastomer, and/or a thermoplastic copolyester. Other portions of the assembly and/or pressure sensor may be formed, in part, using a metal or metal alloy material such as copper, aluminum, and the like. In some embodiments, the apparatus is generally formed of a metal material such as aluminum while parts of the pressure sensor may be formed of thermoplastic and metal material such as copper or aluminum. In order to combine the different materials during the additive manufacturing process, the printer head 308 typically has more than one nozzle as depicted in view 400A and 400B of FIG. 4 so that the printer head 308 can print more than one type of material. In view 400A, the printer head 308 has a first nozzle 410 and a second nozzle 412. For example, the first nozzle 410 may be used to print thermoplastics and the second nozzle 412 may be used to print a first metal (e.g., aluminum). In view 400B, the printer head 308 has the first nozzle, the second nozzle, and a third nozzle 414 for printing a second metal (e.g., copper). The multiple nozzles allow for quick printing of multiple material pressure sensors and assemblies (e.g., aluminum for body of assembly, thermoplastics for body of pressure sensor and/or interconnect insulation, copper for interconnects to pressure sensor, etc.).

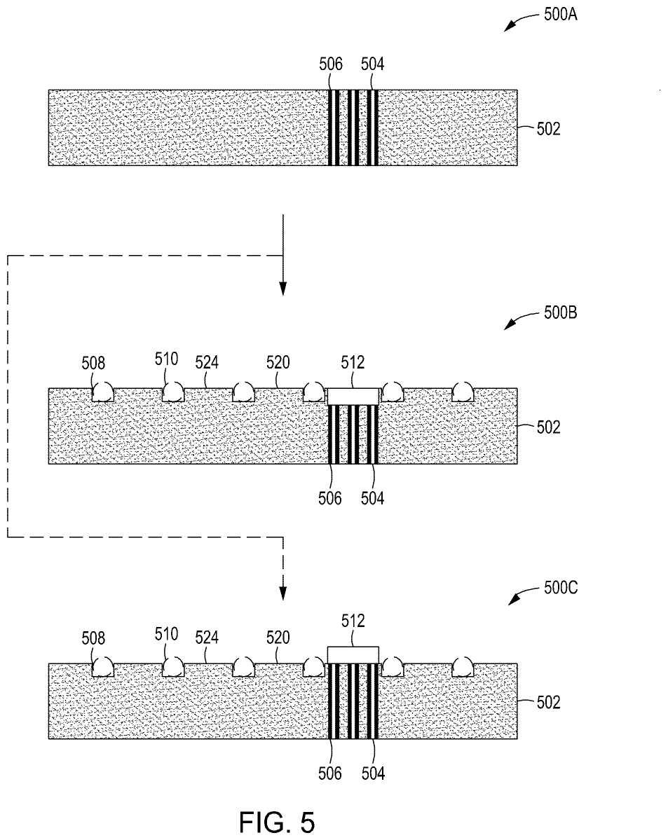

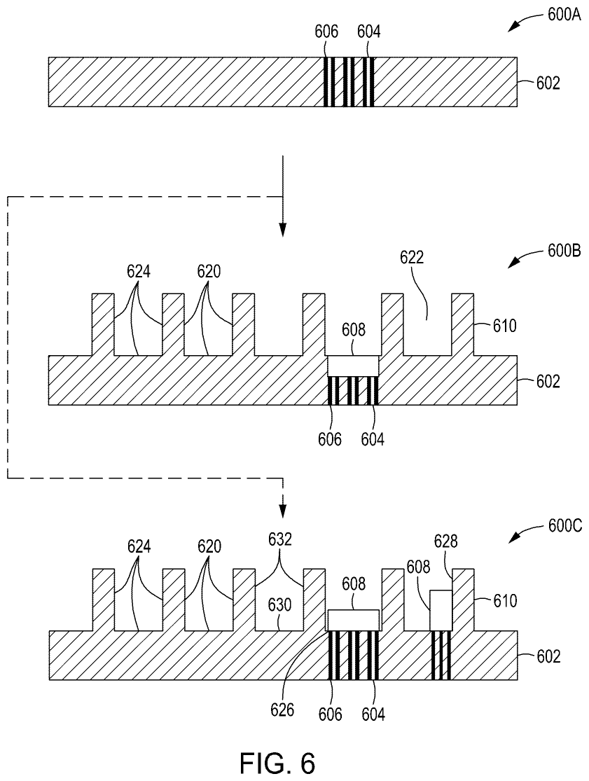

In some embodiments, a method 1300 for forming an apparatus for a process chamber is depicted in FIG. 13. The method 1300 includes formation of the apparatus in conjunction with the formation of the pressure sensor. For the sake of brevity, a showerhead assembly comprising a top plate of a showerhead and a bottom plate of a showerhead will be used as examples. The present principles, however, are not limited to only showerhead assemblies. In block 1302, a body of an apparatus of a process chamber is formed using an additive manufacturing process. In a view 500A of FIG. 5, the body 502 of a top plate apparatus is being formed of a metal material with metal connections 504 surrounded by insulation material 506. In some embodiments, the body and the metal connections may be formed of an aluminum-based material (via a first printing nozzle) and the insulation material 506 may be a PTFE material (via a second printing nozzle). The metal connections may exit through a top, a bottom, or a side of the apparatus. In a view 600A of FIG. 6, a body 602 of a bottom plate is being formed of a metal material with metal connections 604 surrounded by insulation material 606. In some embodiments, the body and the metal connections may be formed of an aluminum-based material (via a first printing nozzle) and the insulation material 606 may be a PTFE material (via a second printing nozzle). The metal connections may be routed and exit through a top, a bottom, or a side of the apparatus. For the sake of brevity, details such as nozzle openings and nozzle passageways have not been shown.

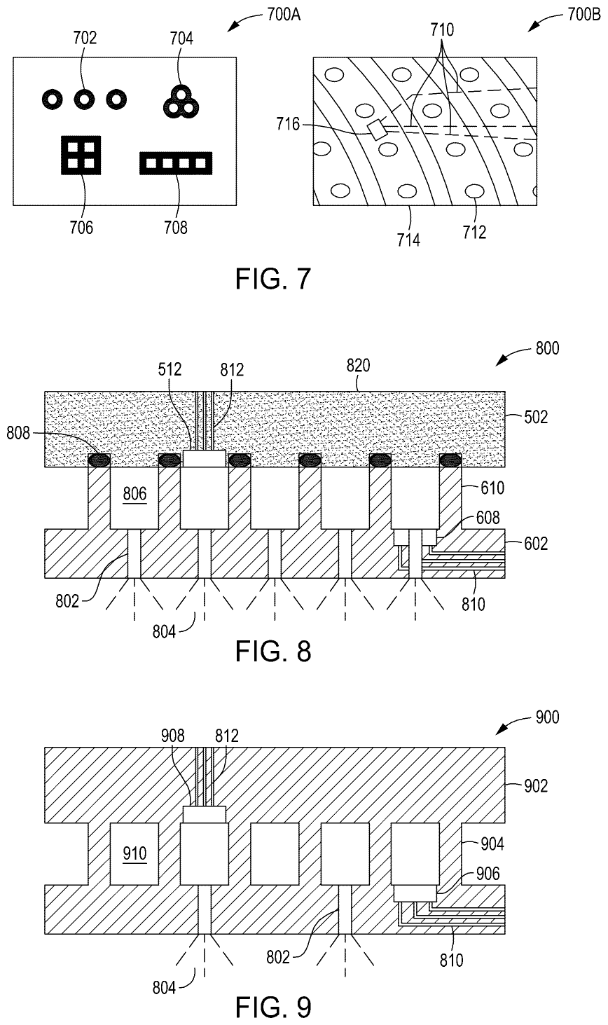

The metal connections may have various shapes and configurations as depicted in a top-down view 700A of FIG. 7. In a first example, the first connections 702 are separated by material of the body in which the connections are formed. In a second example, the second connections 704 are clustered such that connection density is increased and the insulation material forms divisions between the connections. In a third example, the third connections 706 have a square profile and are tightly positioned such that the insulation material is adjacent to more than one connection. In a fourth example, the fourth connections 708 are positioned in a linear fashion such that the insulation material is again shared by more than one connection. Other configurations and profiles (e.g., triangle, oval, rectangle, etc.) are also viable connection selections. The connections may also be twisted together and the like. In some embodiments, the body of the apparatus may have obstacles (gas passages 714, nozzles 712, electrodes, internal structure, etc.) that block a direct path for the connections from the pressure sensor 716 as depicted in a view 700B of FIG. 7. In such cases, the connections 710 may be printed such that the connections are positioned in spaces between the obstacles in a non-linear fashion and the like.

In block 1304 of FIG. 13, one or more first surfaces of the body are formed to channel a first gas at a first gas pressure during the additive manufacturing process. In a view 500B of FIG. 5, the body 502 of the top plate is completed with gasket grooves 508 for supporting a gasket 510 when present and with surfaces 520 that help to contain gases between the gasket grooves 508 when positioned in a process chamber. In a view 600B of FIG. 6, the body 602 of the bottom plate is completed with gas channels 622 with surfaces that help to contain gases in the gas channels 622 when positioned in a process chamber. In optional block 1306, one or more second surfaces of a body may be formed to channel a second gas at a second pressure separate from the first gas during the additive manufacturing process. The second surfaces may be similar to the first surfaces in profile but establish an independent gas channel within the apparatus when positioned in a process chamber. In some embodiments, the second surfaces will be immediately adjacent to the first surfaces. The surface 524 of view 500B of FIG. 5 may be considered an adjacent second surface if different gases flow over the surfaces 520 than over the surface 524. The surfaces 624 of view 600B of FIG. 6 may be considered an adjacent second surface if different gases flow over the surfaces 620 than over the surfaces 624.

In block 1308 of FIG. 13, one or more first gas pressure sensors are formed on one or more first surfaces of a body during the additive manufacturing process. In the view 500B of FIG. 5, the body 502 of the top plate is formed with the pressure sensor 512 embedded into the body 502. In some embodiments, the pressure sensor 512 is formed on top of the surface 520 of the body 502 as depicted in a view 500C of FIG. 5. In the view 600B of FIG. 6, the body 602 of the bottom plate is formed with the pressure sensor 608 embedded into the body 602. In some embodiments, the pressure sensor 608 is formed on top of a bottom surface 626 of the body 602 or on a sidewall surface 628 of a sidewall 610 of the body 602 as depicted in a view 600C of FIG. 6. In optional block 1310 of FIG. 13, one or more second gas pressure sensors are formed that are positioned on one or more second surfaces of a body during the additive manufacturing process. In the view 500B of FIG. 5, a second gas pressure sensor can be formed on or embedded into the body 502, for example, at the surface 524 to monitor a second independent gas channel. Similarly, in the view 600B of FIG. 6, a second gas pressure sensor can be formed on or embedded into the body 602, for example, at the surface 630 or surfaces 632 to monitor a second independent gas channel.

In some embodiments, the apparatus may be fitted together to form a larger assembly. In the case of a bottom plate and a top plate, the two are installed together in the process chamber to form a showerhead. In a view 800 of FIG. 8, the body 502 of the top plate 112 has been flipped over and positioned on top of the body 602 of the bottom plate 120. Compressed gaskets 808 (gasket 116) seal the two apparatus together and form gas channels 806. In the example, connections 812 to the pressure sensor 512 of the top plate exit at the top 820 of the body 502. The connections 810 of the pressure sensor 608 of the body 602 of the bottom plate exit out a side of the bottom plate. The body 602 has nozzle passageways 802 and nozzles 804 to allow gases to be sprayed into the processing volume 128 of the processing chamber 100. The pressure sensor 608 of the body 602 is positioned such that the pressure sensor 608 does not interfere with the operation of the showerhead (e.g., positioned between nozzle passageways 802, etc.). As discussed above, connection routing must also be carefully considered to avoid obstacles within the bodies of the apparatus. The present principles afford the flexibility to do so during the formation of the apparatus, reducing manufacturing costs and time.

In some embodiments, an assembly may be formed as a single monolithic apparatus rather than multiple apparatus that are connected together. In a view 900 of FIG. 9, for example, the body 502 and the body 602 have been formed as a single body 902 with internal sidewalls 904 forming gas channels 910 in the additive manufacturing process. The upper pressure sensor 908 and the lower pressure sensor 906 have both been formed during the formation of the single body 902 of the assembly. In some embodiments, not all of the gas channels 910 have nozzle passageways and not all of the gas channels 910 have pressure sensors. The additive manufacturing process allows for very flexible design choices and can eliminate the need for multi-part assemblies (and sealing surfaces therebetween), reducing overall costs and complexity while still having the abilities to monitor internal pressures.

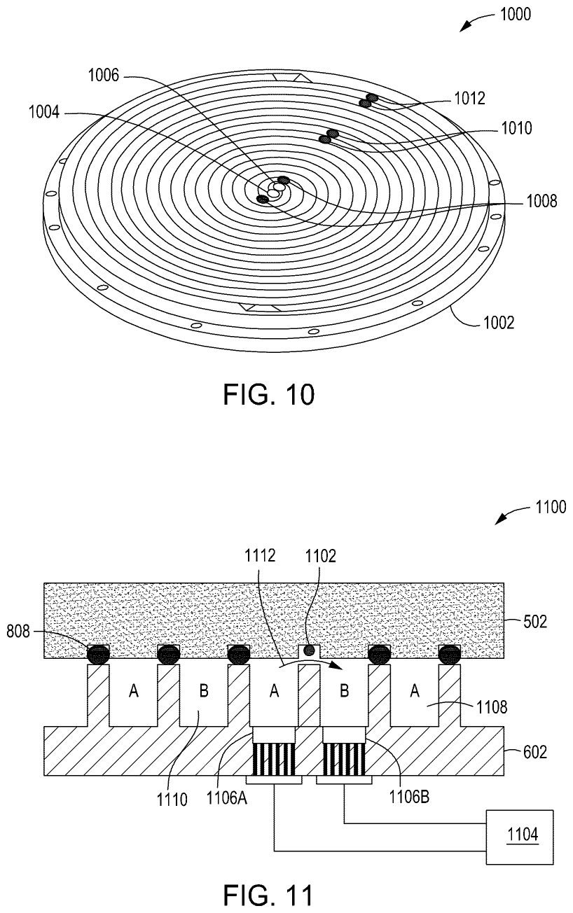

In an isometric view 1000 of FIG. 10, a representative apparatus of a top plate is depicted with a dual channel gas system. The assembly 1002 has a first gas channel 1004 and a second gas channel 1006, separate from the first gas channel 1004. The gas channels when assembled with a bottom plate apparatus form two separated gas channels. Detecting differential pressures between the two independent channels can help to ascertain the operation conditions and/or the sealing conditions between the two channels. A first channel and second channel pair of pressure sensors may be placed at specific locations in order to monitor the pressure differential at key points. In the example of FIG. 10, a first differential pressure sensor pair 1008 is positioned near a center region of the apparatus 1002, a second differential pressure sensor pair 1010 is positioned radially outward of the center region in a middle region of the apparatus 1002, and a third differential pressure sensor pair 1012 is positioned radially outward of the middle region in an outer region of the apparatus 1002. A cross-sectional view 1100 of FIG. 11 depicts a differential pressure pair of pressure sensors positioned in an apparatus comprising a showerhead assembly with a body 602 of a bottom plate and integrated with a body 502 of a top plate. Gasket 808 provides a seal between a first channel A 1108 and a second channel B 1110. A first pressure sensor 1106A monitors the pressure in the first channel A 1108 and a second pressure sensor 1106B monitors the pressure in the second channel B 1110. The first pressure sensor 1106A and the second pressure sensor 1106B are in communication with a differential pressure monitor 1104 (the differential pressure monitor is in communication with the controller 160 (see FIG. 1)).

In the example, the first channel A 1108 has a higher gas pressure than the gas in the second channel B 1110. The gasket 808 has been stretched during installation at point 1102 and is now no longer providing adequate sealing between the two channels. As higher-pressure gas from the first channel A 1108 escapes into the lower-pressure gas channel of the second channel B 1110, the first pressure sensor 1106A will see a drop in pressure and the second pressure sensor 1106B will see a rise in pressure. The differential pressure monitor 1104 will see the pressure differential reach approximately zero as the two channels will attempt to equalize the pressures between the two channels as indicated by the arrow 1112. The differential pressure monitor 1104 can notify the controller 160 and/or the user of the process chamber to indicate a gasket failure or an impending gasket failure (e.g., differential pressure monitor 1104 detects rising/falling pressure at a specific rate and can extrapolate when a total seal failure will occur, etc.). The differential pressure monitor 1104 can also be used to enhance process control by providing real-time differential pressure monitoring during substrate processing.

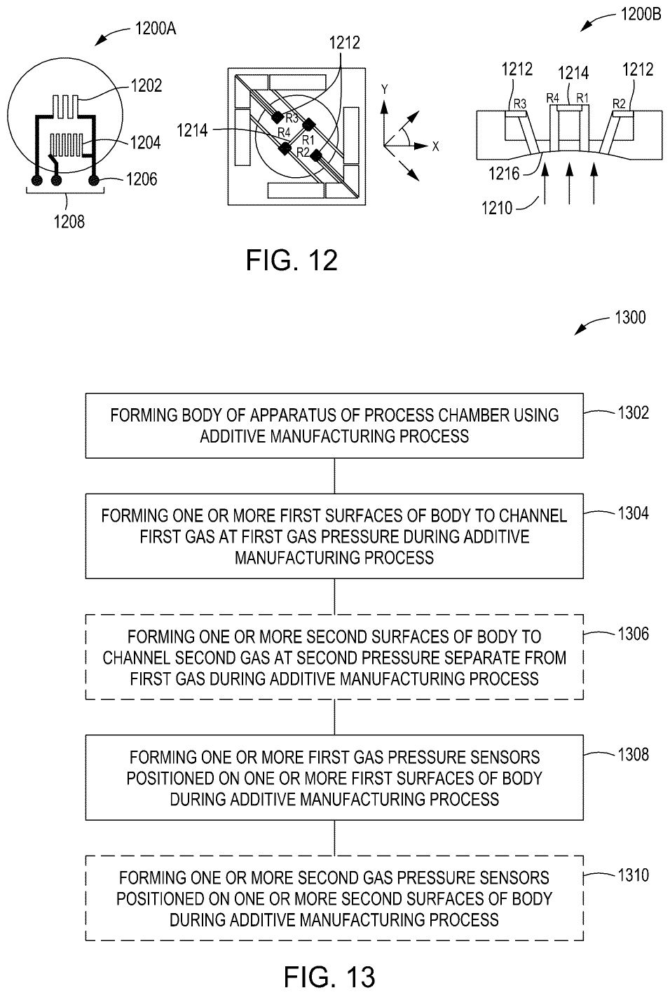

A schematic view 1200A of FIG. 12 depicts a first type of pressure sensor that may be directly printed in or on an apparatus. The pressure sensor uses a strain gauge tensile load 1202 and a strain gauge compressive load 1204 with a common connection 1206, yielding three output connections 1208. The first type of pressure sensor may be, but is not limited to, a 3D printable pressure sensor, for example, as discussed in F. Lucklum and G. Dumstorff, “3D printed pressure sensor with screen—printed resistive read-out,” (2016 IEEE SENSORS, Orlando, FL, USA, 2016, pp. 1-3, doi: 10.1109/ICSENS.2016.7808633). A top-down view 1200B of FIG. 12 depicts a second type of pressure sensor that may be printed directly in or on an assembly. The pressure sensor uses pressure deformation 1210 of the bottom 1216 of the pressure sensor to determine compressive load 1212 at points R2 and R3 and tensile load 1214 at points R1 and R4, yielding four connections. The second type of pressure sensor may be, but is not limited to, a 3D printable pressure sensor, for example, as discussed in Tong, Braiden, et al., “Highly sensitive and robust 3C-SiC/Si pressure sensor with stress amplification structure,” (Materials & Design 224 (2022): 111297). The examples of types of pressure sensors that may be integrated into an assembly is not meant to be limiting as other types (e.g., different pressure parameter detection, multiple leads less than three or greater than four, etc.) and form factors may also be used with the present principles.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for substrate processing in a process chamber, comprising:
a showerhead body;
a first gas channel of the showerhead body; and
one or more first gas pressure sensors positioned at a surface of the first gas channel of the showerhead body.

2. The apparatus of claim 1, further comprising:
a second gas channel of the showerhead body; and
one or more second gas pressure sensors positioned at a surface of the second gas channel of the showerhead body.

3. The apparatus of claim 2, wherein the first gas channel and the second gas channel are both spiral channels that are interleaved with each other.

4. The apparatus of claim 2, further comprising:
a pressure monitor electrically connected to the one or more first gas pressure sensors and the one or more second gas pressure sensors and configured to detect differential pressure between the one or more first gas pressure sensors and the one or more second gas pressure sensors.

5. The apparatus of claim 4, further comprising:
a controller in communication with the pressure monitor and configured to alter a process in the process chamber based on the differential pressure.

6. The apparatus of claim 1, further comprising:
a controller in communication with the one or more first gas pressure sensors and configured to alter a process in the process chamber based on a pressure provided by the one or more first gas pressure sensors.

7. The apparatus of claim 1, wherein the showerhead body is formed by an additive manufacturing process and the one or more first gas pressure sensors are formed by the additive manufacturing process and embedded into the surface of the first gas channel of the showerhead body.

8. The apparatus of claim 7, wherein electrical connections to the one or more first gas pressure sensors are formed through the showerhead body during the additive manufacturing process.

9. The apparatus of claim 1, wherein the showerhead body is formed by an additive manufacturing process and the one or more first gas pressure sensors are formed by the additive manufacturing process and positioned on top of the surface of the first gas channel of the showerhead body.

10. The apparatus of claim 9, wherein electrical connections to the one or more first gas pressure sensors are formed through the showerhead body during the additive manufacturing process.

11. The apparatus of claim 1, wherein the showerhead body comprises two separate pieces with a gasket material positioned therebetween.

12. A method for forming an apparatus for a process chamber, comprising:
forming a showerhead body;
forming a first gas channel of the showerhead body; and
forming one or more first gas pressure sensors positioned at a surface of the first gas channel of the showerhead body using an additive manufacturing process.

13. The method of claim 12, further comprising:
forming a second gas channel of the showerhead body; and
forming one or more second gas pressure sensors positioned at a surface of the second gas channel of the showerhead body using the additive manufacturing process.

14. The method of claim 13, further comprising:
electrically connecting the one or more first gas pressure sensors and the one or more second gas pressure sensors to a controller that detects differential pressure between the one or more first gas pressure sensors and the one or more second gas pressure sensors.

15. The method of claim 14, further comprising:
halting, by the controller, a process in the process chamber based on the differential pressure.

16. The method of claim 12, further comprising:
altering a process in the process chamber based on a pressure provided by the one or more first gas pressure sensors to a controller.

17. The method of claim 12, further comprising:
forming the showerhead body and the one or more first gas pressure sensors using the additive manufacturing process.

18. The method of claim 17, further comprising:
forming electrical connections to the one or more first gas pressure sensors through the showerhead body during the additive manufacturing process.

19. A non-transitory, computer readable medium having instructions stored thereon that, when executed, cause a method for forming an apparatus of a process chamber to be performed, the method comprising:
forming a showerhead body using an additive manufacturing process;
forming a first gas channel of the showerhead body;
forming a second gas channel of the showerhead body;
forming one or more first gas pressure sensors positioned at a surface of the first gas channel during additive manufacturing process; and
forming one or more second gas pressure sensors positioned at a surface of the second gas channel during the additive manufacturing process.

20. The non-transitory, computer readable medium of claim 19, the method further comprising:
forming electrical connections to the one or more first gas pressure sensors and the one or more second gas pressure sensors through the showerhead body during the additive manufacturing process.
